(19) United States
(12) Patent Application Publication
(10) Pub. No.: US 2025/0115198 A1
(43) Pub. Date: Apr. 10, 2025

(54) HIGH VOLTAGE JUNCTION BOX

(71) Applicants: HYUNDAI MOTOR COMPANY, Seoul (KR); KIA CORPORATION, Seoul (KR); YURA CORPORATION CO., LTD., Seongnam-si (KR)

(72) Inventors: Mun Jong KIM, Hwaseong-si (KR); Jin Woo JUNG, Seoul (KR)

(21) Appl. No.: 18/887,491

(22) Filed: Sep. 17, 2024

(30) Foreign Application Priority Data
Oct. 10, 2023 (KR) 10-2023-0134456

(51) Int. Cl. B60R 16/023; B60R 16/033; B60R 16/06; H02G 3/18; H02G 5/08

(52) U.S. Cl. CPC B60R 16/0239; B60R 16/033; B60R 16/06; H02G 3/18; H02G 5/08

(57) ABSTRACT

A high voltage junction box in a vehicle is powered by an electric motor. The high voltage junction box includes a housing made of a non-metallic material, the housing having a female connector installation hole, a housing cover made of a non-metallic material, a female connector disposed in the female connector installation hole, and a ground bus bar disposed at the housing and configured to connect the female connector to a vehicle body. The high voltage junction box improves the capability of absorbing radiated noise through a ground bus bar that allows surface grounding and has low wiring resistance.

### CROSS-REFERENCE TO RELATED APPLICATIONS

The present application claims priority to Korean Patent Application No. 10-2023-0134456, filed on Oct. 10, 2023, the entire contents of which are incorporated herein for all purposes by this reference.

### TECHNICAL FIELD

The present disclosure relates to a high voltage junction box in a vehicle powered by an electric motor.

### BACKGROUND

Some vehicles include electric motors used as a power source.

For instance, an electric motor that powers a vehicle is supplied with high-voltage electricity through a high-voltage battery, and the high-voltage components of the high-voltage battery may be used. In some cases, the high-voltage components for supplying electricity from a battery to an electric motor are organically and complexly connected to each other.

A high voltage junction box may be used to distribute such a high voltage power. A junction may refer to an intersection, a confluence, or a connection point, and a vehicle's high-voltage is gathered in a high-voltage junction box and then sent to each component. In some cases, a high-voltage junction block serves as a power distributor that connects the high voltage of a high-voltage battery with other components.

In some cases, high-voltage junction boxes may be made of aluminum and therefor have high efficiency in conductivity and shielding. In some cases, metal materials may lead to a heavy weight, expensive raw material costs, and processing costs.

In some cases, shielding plastic may have a lower conductivity than aluminum and thus have limitations in noise absorption and transmission. In some cases, referring to FIGS. 1A and 1B, a ground wire 20 may be applied to a high voltage junction box 10. The ground wire absorbs radiated noise generated by power flow and radiates it to vehicle chassis.

When radiated noise is removed using a ground wire, the shielding capability may deteriorate due to the high resistance of the ground wire.

### SUMMARY

The present disclosure describes a new type of high-voltage junction box that absorbs radiated noise through a ground bus bar that allows surface grounding and has low wiring resistance.

According to one aspect of the subject matter described in this application, a high voltage junction box includes a housing made of non-metallic material and having at least one female connector installation hole, a housing cover made of non-metallic material, at least one female connector installed in the female connector installation hole, and at least one ground bus bar installed in the housing and configured to allow the at least one female connector to contact a vehicle body.

Implementations according to this aspect can include one or more of the following features. For example, the female connector may include a connector connection portion and a coupling portion extending from the connector connection portion and coupled to the female connector installation hole.

In some implementations, the female connector may further include a shielding plate, and at least a portion of the shielding plate is exposed at the coupling portion.

In some implementations, the ground bus bar may include a first bus bar grounded with the shielding plate and comprising a first bolt hole.

In some implementations, the ground bus bar may include a second bus bar grounded to the shielding plate and having a coupling body including a first bolt groove and a second bolt groove which are longitudinally symmetrical.

In some implementations, the housing may further include a bus bar hole, and the coupling body may be installed in the bus bar hole.

In some implementations, the ground bus bar may include a third bus bar having a second bolt hole and a third bolt hole.

In some implementations, a sealing member may be installed between the bus bar hole and the coupling body.

In some implementations, the first bolt hole is coupled to the first bolt groove with a bolt and the third bolt hole is coupled to the second bolt groove with a bolt.

In some implementations, the ground bus bar may further include a lance locking portion, and the housing may further include a lance locking groove.

In some implementations, the ground bus bar may further include a snap-fit coupling hole, and the housing may further include a snap fit.

The high voltage junction box In some implementations may further include an anti-rotation protrusion spaced apart from the snap fit.

In some implementations, the non-metallic material may include shielding plastic.

In some implementations, it may be possible to improve the capability of absorbing radiated noise through a ground bus bar that allows surface grounding and has low wiring resistance.

Because a shielding capability is enhanced when a high-voltage junction box made of shielding plastic has the same grounding structure of “surface grounding” as a high-voltage junction box made of aluminum, it may be possible to secure a shielding capability when a high-voltage junction box made of shielding plastic is stably coupled to vehicle chassis by applying a grounding bus bar.

The effects of the present disclosure are not limited to the above-mentioned effects, and the following description would allow a person having ordinary skill in the technical field to which the present disclosure pertains to clearly understand other effects not mentioned above.

The methods and apparatuses of the present disclosure have other features and advantages which will be apparent from or are set forth in more detail in the accompanying drawings, which are incorporated herein, and the following Detailed Description, which together serve to explain certain principles of the present disclosure.

### BRIEF DESCRIPTION OF THE DRAWINGS

FIGS. 1A and 1B are views illustrating a junction box with a ground wire in related art.

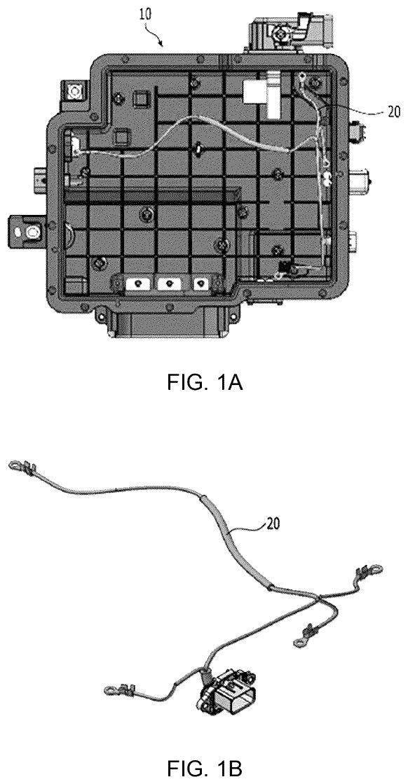

FIG. 2 is an exploded view illustrating an example of a high voltage junction box with a ground bus bar according to the present disclosure.

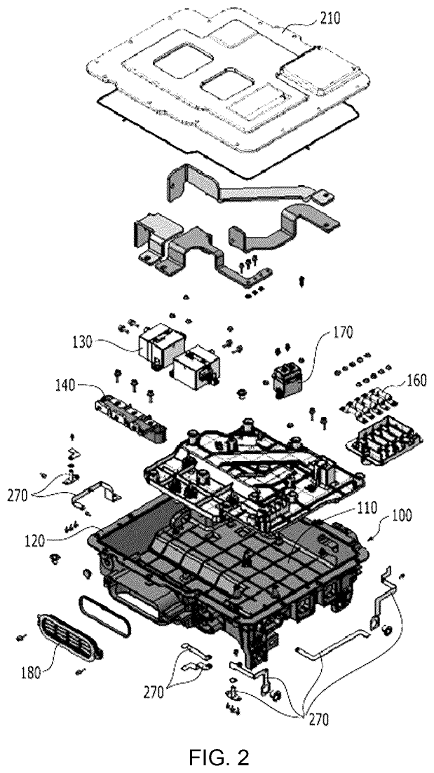

FIG. 3 is a view for illustrating a top surface of the high voltage junction box with the ground bus bar and without a housing cover.

FIG. 4 illustrates the female connector coupled to the coupling hole of the housing of the high voltage junction box with the ground bus bar.

FIGS. 5A and 5B illustrate the ground bus bar installed in the high voltage junction box with the ground bus bar.

FIG. 6 shows how the female connector of the high voltage junction box with the ground bus bar is grounded to a vehicle body by the ground bus bar.

FIGS. 7A to 7C show an example structure in which the ground bus bar of the high voltage junction box with the ground bus bar is fixed.

FIG. 8 shows an example structure in which the ground bus bar of the high voltage junction box with the ground bus bar is fixed.

### DETAILED DESCRIPTION

Hereinafter, one or more example implementations of the present disclosure will be described in detail with reference to the attached drawings. Components identical or corresponding to one other have the same reference number regardless of their drawing reference numbers, and the description thereof will not be repeatedly provided.

In some implementations, the high voltage junction box may include a housing 100, a housing cover 210, a female connector 220, and a ground bus bar 270.

The housing 100 may be made of a non-metallic material. In some examples, the housing 100 may be made of shielding plastic. The housing 100 may be in the shape of a rectangular box with a bottom 110 and a side wall 120.

The side wall 120 may be formed with a plurality of female connector installation holes 190 where the female connector 220 is installed.

The housing 100 may accommodate its components therein. The components may include at least one of the side wall 120, a terminal block 140, a fuse case 150, a HV fuse 160, and a HV relay 170.

In some examples, an air vent 180 may be formed on the side wall 120 of the housing 100 to keep the pressure inside the housing 100 constant even when the temperature outside the housing 100 changes.

In addition, the side wall 120 of the housing 100 may further include a bus bar hole into which the coupling body of a first bus bar 280, which will be described below, is inserted.

The housing cover 210 may be made of a non-metallic material. In some examples, the housing cover 210 may be made of the same shielding plastic as the housing 100.

A plurality of female connectors 220 may be provided and installed in the female connector installation hole 190 formed on the housing 100.

The female connector 220 may include a connector connection portion 230 to which a connector is connected and a coupling portion 240 extending from the connector connection portion 230 and coupled to the female connector installation hole 190.

The female connector 220 may have a shielding plate 250 therein.

At least a portion of the shielding plate 250 may be exposed to the outside at the coupling portion 240. A through hole 260 may be formed on the coupling portion 240 to allow the shielding plate 250 to be exposed to the outside.

At least one ground bus bar 270 may be installed in the housing 100 to ground at least one female connector 220 and a vehicle body.

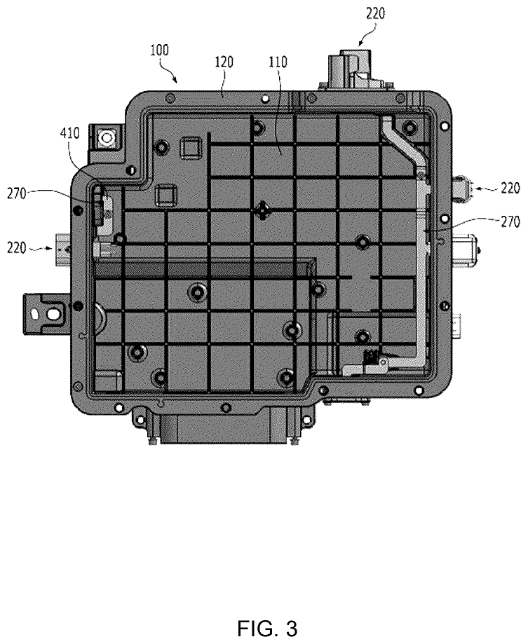

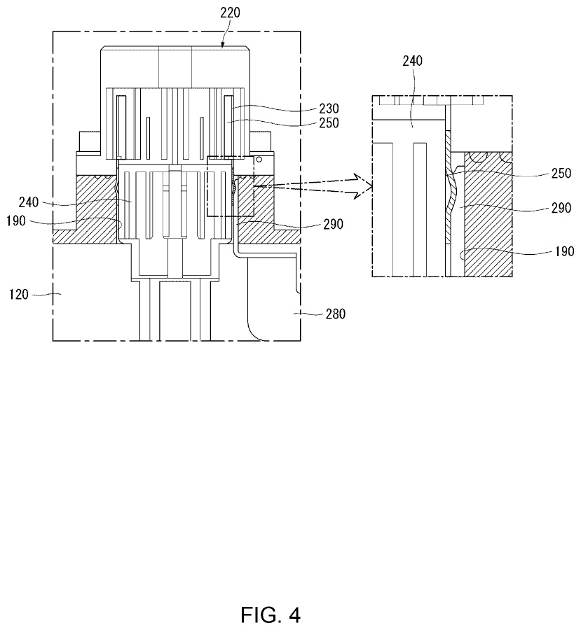

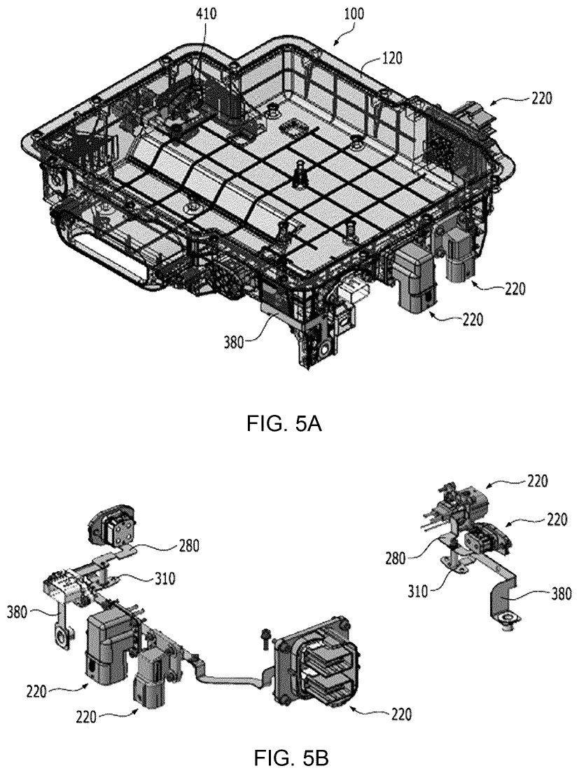

As shown in FIGS. 3 to 5B, the ground bus bar 270 may be formed by combining a first bus bar 280, a second bus bar 310, and a third bus bar 380, which will be described below, in series or parallel.

The first bus bar 280, the second bus bar 310, and the third bus bar 380 may have a plurality of ground portions to be connected to the connector.

The ground bus bar 270 may include the first bus bar 280, the second bus bar 310, and the third bus bar 380.

A first ground portion 290 grounded to the shielding plate 250 may be formed at one end of the first bus bar 280, and a first bolt hole 300 may be formed at the other end.

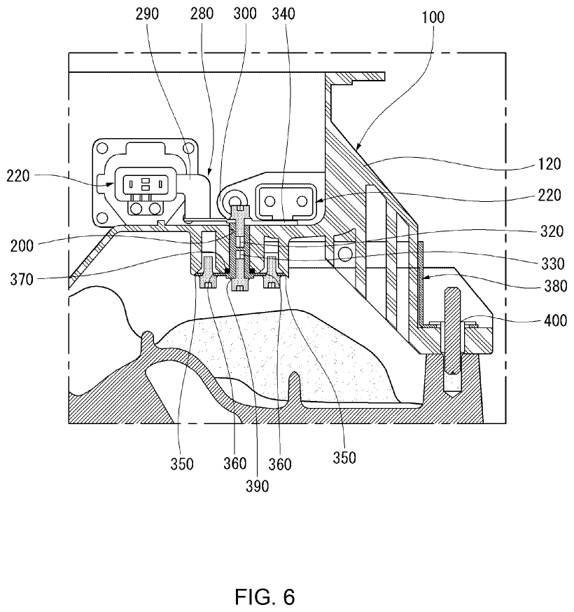

The first bus bar 280 may be placed inside the housing 100 as shown in FIG. 6.

The first ground portion 290 of the first bus bar 280 may be firmly fixed by being press-fitted between the coupling portion 240 and the inner wall of the female connector installation hole 190.

At one end of the second bus bar 310, a coupling body including a first bolt groove 320 and a second bolt groove 330 that is longitudinally symmetrical with the first bolt groove 320 may be formed, and a second ground portion 340 grounded to the shielding plate may be formed at the other end of the second bus bar 310. The coupling body may be coupled to the bus bar hole.

The second ground portion 340 may extend from the entrance of the first bolt groove 320.

In addition, the second bus bar 310 may include fixing portions 350 extending from the entrance of the second bolt groove 330 to both sides. A fourth bolt hole 360 may be formed on the fixing portion 350 so that the second bus bar 310 may be fixed to the housing 100 with a bolt.

Furthermore, a sealing member may be formed on the outer surface of the coupling body of the second bus bar 310. In some examples, the sealing member may be an O-ring 370 made of rubber.

The O-ring 370 may be placed between the fixing portion 350 and the housing 100 and may serve to block moisture or foreign substances from entering the interior.

In some implementations, in order to better block foreign substances, the space between the housing 100 and the fixing portion 350 may be shielded by a rubber plate having the same area as the fixing portion 350 and the same through hole as the fourth bolt hole 360, instead of the O-ring 370.

A second bolt hole 390 may be formed at one end of the third bus bar 380, and a third bolt hole 400 may be formed at the other end.

Referring to FIG. 6, the first bolt hole 300 of the first bus bar 280 may be coupled to the first bolt groove 320 of the second bus bar 310 with a bolt.

In addition, the third bus bar 380 may be coupled to the second bolt hole 390 at one end thereof and the second bolt groove 330 of the second bus bar 310 with a bolt. The third bolt hole 400 of the third bus bar 380 may be coupled to a vehicle body with a bolt, so that the shielding plate 250 of the female connector 220 may be grounded with the vehicle body.

The first to third bus bars 280 to 380 may be connected to each other at their ends to be long in the longitudinal direction, and, when the middle portion of the first to third bus bars 280 to 380 installed in the housing 100 is not fixed, a short circuit may occur due to high voltage when they come into contact with parts inside the housing 100.

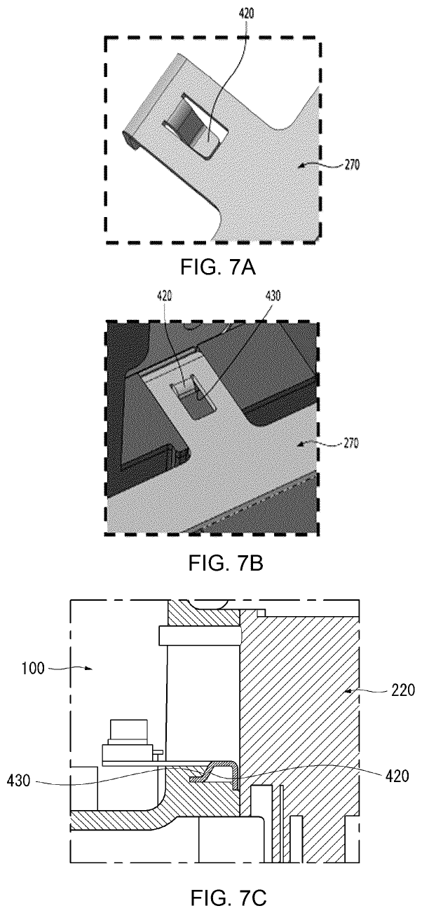

To prevent such a problem, as shown in FIGS. 7A to 7C, the first to third bus bars 280 to 380 may be formed with a lance locking portion 420 to be fixed to the housing 100. In addition, a lance locking groove 430 may be formed in the housing 100 to allow the lance locking portion 420 to be coupled thereto.

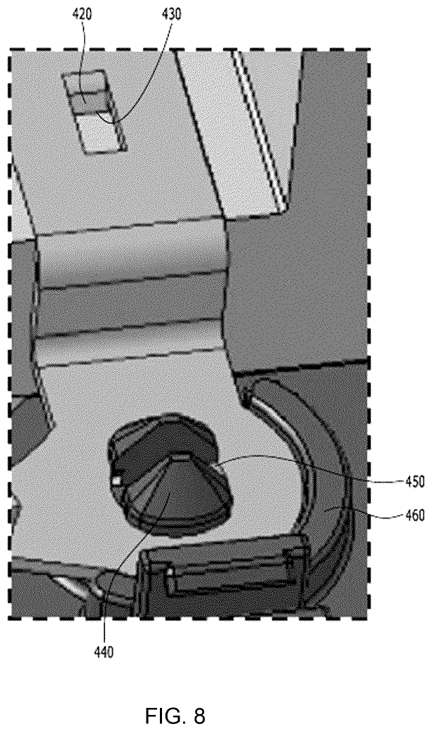

In some implementations, a snap fit 440 may be formed on the housing 100 as shown in FIG. 8. A snap-fit coupling hole 450 may be formed on the first to third bus bars 280 to 380 so that the snap fit 440 may be coupled thereto. When connecting the snap-fit coupling hole 450 formed on at least one of the first to third bus bars 280 to 380 to the housing 100 using the snap fit 440, rotation may occur around the snap fit 440. To prevent such a problem, an anti-rotation protrusion 460 spaced apart from the snap fit 440 by a set distance may be formed on the housing 100.

The lance locking groove 430 may be formed inside the housing 100. As a result, there are no protruding parts as shown in FIGS. 7A to 7C, so it may be possible to use space more easily when installing parts inside the housing 100.

The snap fit 440 may be formed on the outer surface of the housing 100. Fixing through the snap fit 440 may have a similar fixing force as fixing through bolts, so it may be possible to fix the ground bus bar 270 and prevent it from falling off even when it is bent due to an impact, etc. outside the housing 100, etc.

The ground bus bar 270 may further include a fourth bus bar 410. The fourth bus bar 410 may be grounded to a vehicle separately from the first to third bus bars 280 to 380. The fourth bus bar 410 may differ from the first to third bus bars 280 to 380 only in shape and may have the same role, so a detailed description thereof will not be provided.

The width of the thinnest portion of the first to fourth bus bars 280 to 410 may be at least 10 mm.

The description has been made focusing on the implementations of the present disclosure, but the implementations are only illustrative and are not intended to limit the present disclosure. A person having ordinary skill in the art would be understand that various modifications and applications that have not been described above can be made to the implementations within the essential features thereof. For example, each of the components specifically described for the implementations can be modified. In addition, the differences resulting from such modifications and applications should be deemed to be within the scope of the present disclosure defined by the appended claims.

The foregoing descriptions of the specific exemplary implementations of the present disclosure have been presented for the purposes of illustration and description. They are not intended to be exhaustive or to limit the present disclosure to the precise forms disclosed, and obviously many modifications and variations are possible in light of the above-described teachings. The exemplary implementations were chosen and described to explain certain principles of the present disclosure and their practical application, to enable others skilled in the art to make and utilize the various exemplary implementations of the present disclosure, as well as various alternatives and modifications thereof. It is intended that the scope of the present disclosure be defined by the claims appended hereto and their equivalents.

What is claimed is:

1. A high voltage junction box, comprising
a housing made of a non-metallic material, the housing having a female connector installation hole;
a housing cover made of a non-metallic material;
a female connector disposed in the female connector installation hole; and
a ground bus bar disposed at the housing and configured to allow the female connector to contact a vehicle body.

2. The high voltage junction box of claim 1, wherein the female connector comprises:
a connector connection portion; and
a coupling portion that extends from the connector connection portion and is coupled to the female connector installation hole.

3. The high voltage junction box of claim 2, wherein the female connector further comprises a shielding plate, and at least a portion of the shielding plate is exposed at the coupling portion.

4. The high voltage junction box of claim 3, wherein the ground bus bar comprises a first bus bar that is connected to the shielding plate, the first bus bar having a first bolt hole.

5. The high voltage junction box of claim 4, wherein the ground bus bar further comprises a second bus bar that is connected to the shielding plate, the second bus bar comprising a coupling body that defines a first bolt groove and a second bolt groove that are symmetrical.

6. The high voltage junction box of claim 5, wherein the housing defines a bus bar hole that accommodates the coupling body of the second bus bar.

7. The high voltage junction box of claim 6, wherein the ground bus bar further comprises a third bus bar that defines a second bolt hole and a third bolt hole.

8. The high voltage junction box of claim 6, further comprising a sealing disposed between the bus bar hole and the coupling body.

9. The high voltage junction box of claim 7, wherein the first bolt hole is coupled to the first bolt groove with a bolt, and
wherein the third bolt hole is coupled to the second bolt groove with a bolt.

10. The high voltage junction box of claim 1, wherein the ground bus bar further comprises a lance locking portion, and
wherein the housing defines a lance locking groove coupled to the lance locking portion.

11. The high voltage junction box of claim 1, wherein the ground bus bar defines a snap-fit coupling hole, and
wherein the housing further comprises a snap fit coupled to the snap-fit coupling hole.

12. The high voltage junction box of claim 11, further comprising an anti-rotation protrusion spaced apart from the snap fit.

13. The high voltage junction box of claim 1, wherein the non-metallic material of at least one of the housing or the housing cover comprises a shielding plastic.

14. The high voltage junction box of claim 1, wherein the non-metallic material of each of the housing and the housing cover comprises a shielding plastic.

15. The high voltage junction box of claim 1, wherein the female connector installation hole is one of a plurality of female connector installation holes defined at the housing,
wherein the female connector is one of a plurality of female connectors that are disposed in the plurality of female connector installation holes, respectively, and
wherein the ground bus bar is one of a plurality of ground bus bars that are disposed at the housing and configured to allow the plurality of female connectors to contact the vehicle body, respectively.
